(19) United States
(12) Patent Application Publication
(10) Pub. No.: US 2006/0244539 A1
(43) Pub. Date: Nov. 2, 2006

(54) Output circuit for amplifying and outputting an input signal

(75) Inventor: Noboru Takatsuka, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/399,526

(22) Filed: Apr. 7, 2006

(30) Foreign Application Priority Data
Apr. 27, 2005 (JP) 2005-129498

(51) Int. Cl. H03F 3/04

(52) U.S. Cl. 330/297

(57) ABSTRACT

An output circuit includes a first amplifier that is supplied with power via a first power supply line that receives an input signal, and a second amplifier that further amplifies a signal amplified by the first amplifier and is supplied with power via a second power supply which is independent from the first power supply line.

### BACKGROUND OF THE INVENTION

1. Field of the Invention

The present invention relates to an output circuit for amplifying and outputting an input signal, and particularly to an output circuit provided in a semiconductor integrated circuit. More specifically, this invention relates to an output circuit for amplifying and outputting a signal charge in a solid-state image sensing device.

2. Description of Related Art

An output circuit illustrated in FIG. 4 has been used to amplify and output a signal charge in a solid-state image sensing apparatus. An output circuit 10 photoelectrically converts an incident light by means of a photodiode, amplifies and outputs the photoelectrically converted electrical signal (input signal) The output circuit 10 is comprised of an amplifier A11 and a source follower S11 for activating an external circuit. Power is supplied to the amplifier A11 and the source follower S11 by providing a power supply VDD1 via a common power supply line.

In the output circuit 10, a modulated current Im that is caused by an input signal is generated when the input signal in response to an incident light is amplified in the output circuit. By the modulated current Im passing through a power supply line of a resistance Rv, a power supply voltage fluctuates as in ΔV=Im×Rv. The fluctuation of the power supply voltage induces a characteristic fluctuation of the amplifier A11, consequently fluctuating an output signal as well as causing an output waveform distortion.

An output circuit for improving the waveform distortion is disclosed in Japanese Patent No. 3106436. A configuration of the output circuit described in Japanese Patent No. 3106436 is illustrated in FIG. 5. An output circuit 11 has independent power supplies for each of a source follower S11 and an amplifier A11. Modulated current is generated mainly because of a source follower. This technique reduces waveform distortion by separating power supply lines to be connected to the amplifier A11 and the source follower S11 so as to prevent from passing a fluctuation of a power supply voltage caused by a modulated current of the source follower S11 to the amplifier All.

In an actual circuit, two-stage amplifiers are occasionally used as a previous stage of a source follower. The inventor then has suggested a configuration illustrated in FIG. 6 based on the configuration in FIG. 5 when having a plurality of amplifier stages.

However it has been discovered from an experiment that a waveform distortion is greater than expected. Moreover the level of the waveform distortion is recognized to be inappropriate for a CCD output circuit of a solid-state image sensing device.

### SUMMARY OF THE INVENTION

According to an aspect of the present invention, there is provided an output circuit that includes a first amplifier to which power is supplied via a first power supply line that receives an input signal, and a second amplifier that further amplifies an output signal from the first amplifier and to which power is supplied by a second power supply line which is independent from the first power supply line.

That is, a fluctuation in power supply voltage caused by a modulated current which is generated in the second amplifier will not influence the power supply to the first amplifier because the power supply is separated for the first and the second amplifier. It indicates that an output fluctuation caused by a modulated current will neither be amplified by the first nor the second amplifier. A waveform distortion in the output signal from the output circuit can therefore be reduced in this way.

### BRIEF DESCRIPTION OF THE DRAWING

The above and other objects, advantages and features of the present invention will be more apparent from the following description taken in conjunction with the accompanying drawings, in which:

FIG. 1 is a view showing the configuration of an output circuit according to a first embodiment of the present invention;

FIG. 2 is a view showing the configuration of an output circuit according to a second embodiment of the present invention;

FIG. 3 is a view showing the configuration of an output circuit according to a third embodiment of the present invention;

FIG. 4 is a view showing the configuration of an output circuit according to a conventional technique;

FIG. 5 is a view showing another configuration of an output circuit according to a conventional technique; and

FIG. 6 is a view showing a further configuration of an output circuit according to a conventional technique.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

Am embodiment of the present invention is described hereinafter with reference to the drawings.

FIG. 1 is a view showing an output circuit 100 according to a first embodiment of the invention. A1 and A2 are amplifiers and S1 is a source follower having similar function to those in a conventional technique. Inverting amplifiers comprised of NMOS inverters may be used for the amplifiers A1 and A2. The amplifier A1 inverts and amplifies in response to an input signal IN. The signal amplified by the amplifier A1 is inputted into the amplifier A2, further inverted, amplified, and then outputted as an output signal OUT via the source follower S1. Note that in case of an output circuit for a solid-state image sensing device, the output signal OUT is often received by an emitter follower.

To avoid an influence from a power supply voltage fluctuation among a plurality of amplifiers, the amplifiers and source follower should be individually supplied with power. However for an output circuit provided in a semiconductor integrated circuit, only two independent power supply lines may be allowed to be provided due to layout limitation.

Therefore as shown in FIG. 6, the inventor has thought of separating power supply to amplifiers A11 and A21 from power supply to a source follower S11, so that a fluctuation in power supply voltage caused by a modulated current of the source follower S11 will not affect the amplifiers A11 and A21. There still exists a modulated current to be generated caused by the amplifiers, though its amount is less than the modulated current produced by the source follower. Further, an output voltage from an inverting amplifier is sensitive to a power supply voltage fluctuation. Accordingly the inventor has considered that a waveform distortion in an output signal from an output circuit 10 can be larger even if a modulated current generated by the amplifier A21 is small. This is because a power supply voltage fluctuation that is causing the modulated current fluctuates an output signal of the amplifier A11 which is connected to a common power supply line, and consequently the fluctuated output signal is further amplified by the amplifier A21.

As a result of various experiments conducted by the inventor under the foregoing consideration, a conclusion is drawn that to provide the amplifier A2 and the source follower S1 with a power supply VDD1 via a common power supply line, and to provide the amplifier A1 with a power supply VDD2 via a power supply line 2 which is independent from the power supply line 1. That is, the power supply line 2 for supplying the power supply VDD2 to the amplifier A1 is electrically separated from the power supply line 1 for supplying the power supply VDD1 to the amplifier A2 and the source follower S1. As described in the foregoing, by separating the power supply to the amplifier A2 and the source follower S1 from the power supply to the amplifier A1, no influence of voltage fluctuation ΔV caused by a modulated current Im is to be exerted on the amplifier A1 even when the modulated current Im is generated by the amplifier A2 and the source follower S1. In this way, the amplifier A2 will not further amplify a signal outputted and fluctuated by a power supply voltage fluctuation.

Although the modulated current Im is generated mainly due to the source follower S1, the modulated current Im becomes relatively small because an emitter follower connected in a subsequent stage of the source follower S1 is driven with a current Hence even when a modulated current is generated by the source follower S1, the modulated current has only a small influence of a power supply voltage fluctuation arising from the modulated current on the amplifier A2. Moreover an output from the source follower S1 hardly changes along with a change in power supply voltage.

Therefore, even if power is supplied to the amplifier A2 and the source follower S1 via a common power supply line 1, an output waveform distortion can effectively be reduced by electrically separating power supply lines for the amplifier A1 and the amplifier A2.

### Second Embodiment

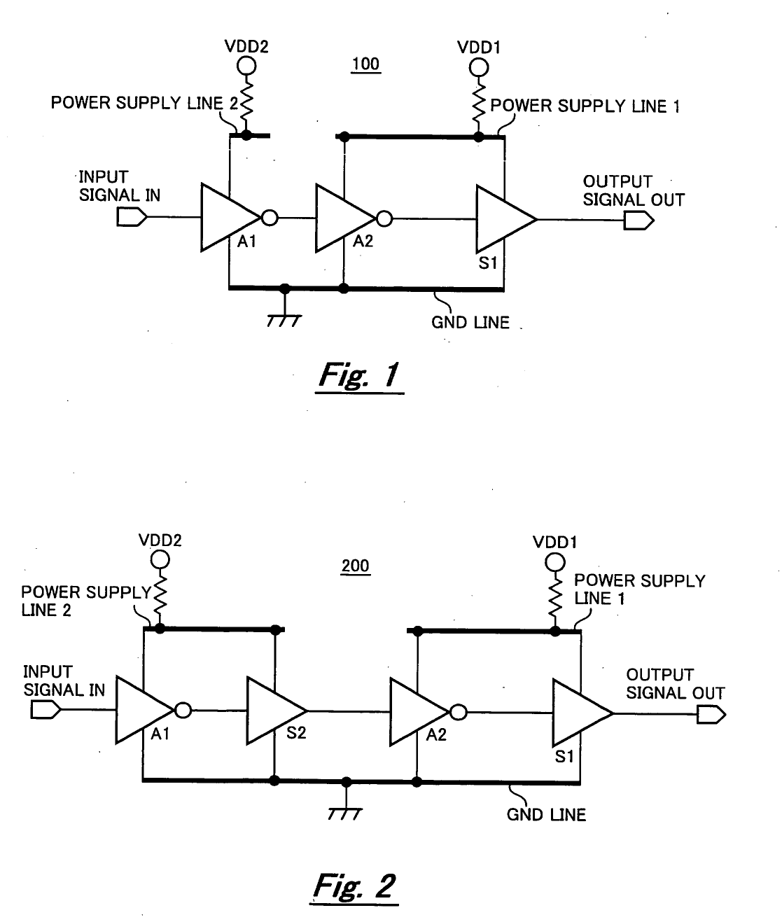

FIG. 2 shows the configuration of an output circuit 200 according to a second embodiment of the invention. As in the case of the first embodiment illustrated in FIG. 1, an output circuit 2 includes amplifiers A1, A2 and a source follower S1. In FIG. 2, constituents identical to those in FIG. 1 are denoted by reference numerals identical to those therein with detailed description omitted.

Unlike the circuit in FIG. 1, a source follower S2 is connected in a subsequent stage of the amplifier A1 in the output circuit 2. The source follower S2 is provided so as to adjust a voltage operation point of the amplifier A2. A power supply VDD2 is provided to the source follower S2 and the amplifier A1 via a common power supply line 2. A power supply to the amplifier A2 and the source follower S1 is provided independently from a power supply to the amplifier A1 and the source follower S2.

Despite that the amplifier A1 and the source follower S2 are supplied with power via a common power supply line 2, a modulated current caused by the source follower S2 is relatively small, considering that the amplifier A2 which is connected to the source follower 2 is an inverting amplifier comprised of NMOS inverters and is driven by a current. Therefore even when a modulated current is generated by the source follower S2, there is only a small influence of a power supply voltage fluctuation arising from the modulated current on the amplifier A1.

As described above, the configuration reduces an influence of a power supply voltage fluctuation between the amplifiers A1 and A2 as well as a waveform distortion in an output signal OUT.

### Third Embodiment

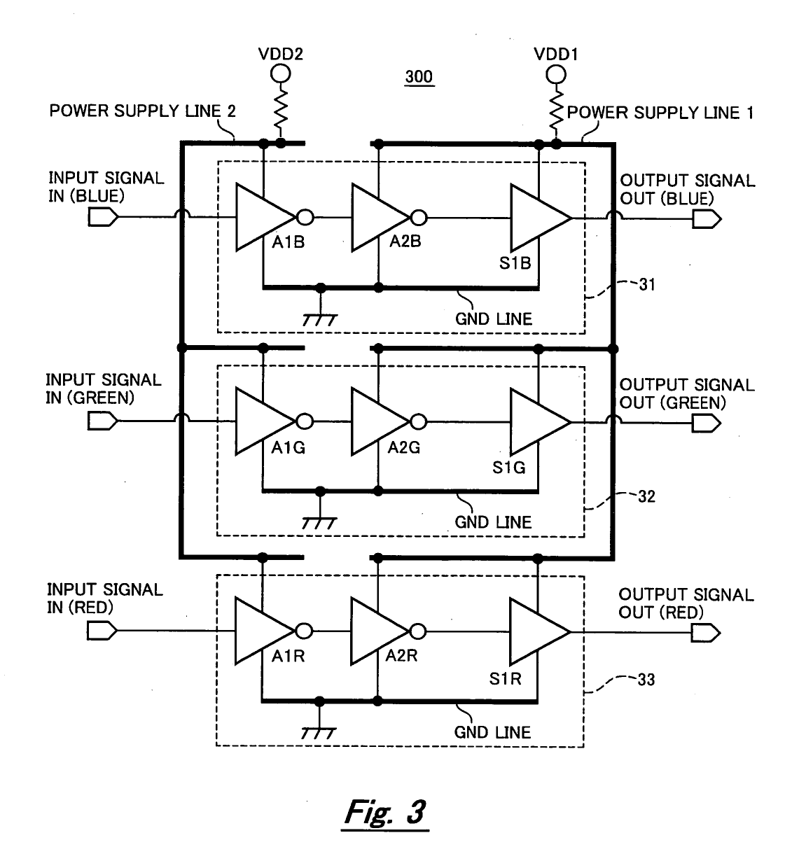

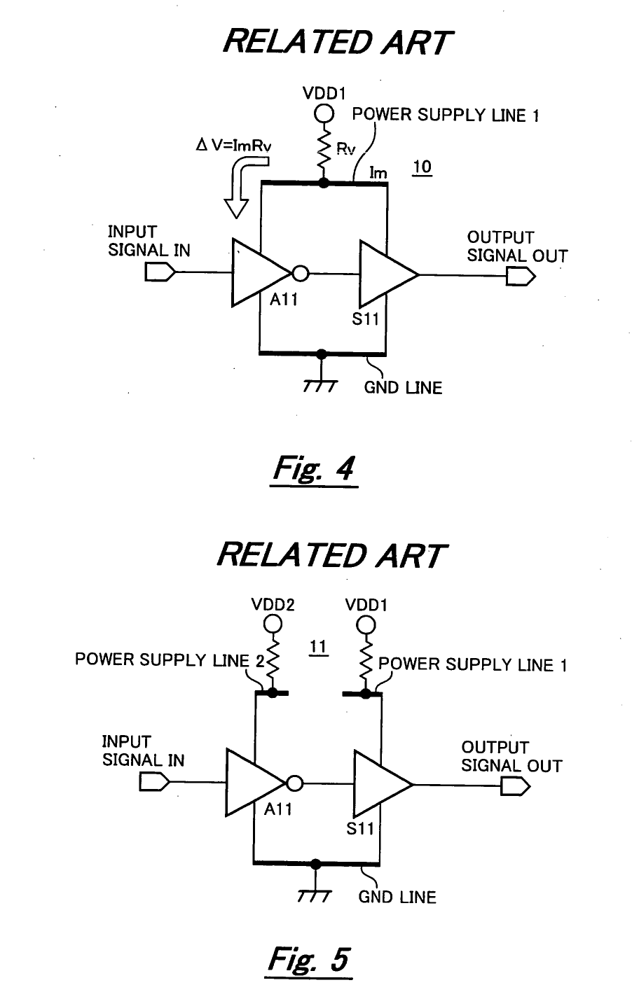

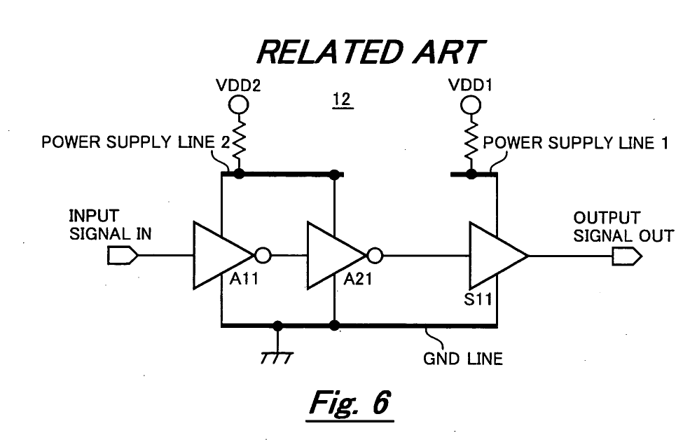

FIG. 3 is a view showing an output circuit 3 according to a third embodiment of the invention.

The output circuit 300 shows an example when applying the third embodiment to a color CCD solid-state image sensing device in which color filters in blue, green, and red are formed on a light-receiving section. As shown in FIG. 3, output circuit sections 31, 32, and 33 are provided respectively to input signals IN (blue), IN (green), and IN (red) that correspond to each color. The configuration of the output circuit section 31 is described hereinafter as the configuration of the output circuits sections 31 to 33 are substantially the same.

The output circuit section 31 receives an input signal IN (blue), amplifies the input signal IN (blue) by amplifiers A1B and A2B, and outputs it as an output signal OUT (blue) via a source follower S1B. A power supply VDD2 is provided to amplifiers A1B, A1G and A1R in an initial stage via a common power supply line 2 that are included respectively in the output circuit sections 31 to 33. Other amplifiers A2B, A2G, A2R, source followers S1B, S1G and S1R are provided with a power supply VDD1 via a common power supply line 1 which is independent from the power supply line 2.

The configuration described in the foregoing reduces waveform distortion in each output signals of the output circuit sections corresponding to the three colors.

As this embodiment is specifically described according to the present invention, in an output circuit having a plurality of amplifiers, reduction of waveform distortion in output signal can be achieved by individually providing power to the amplifier A1 and A2. In the above embodiments, all GND lines are used in common, however by electrically separating the GND line in the same manner as the power supply line, waveform distortion in output signal can further be reduced. Although this embodiment used an output circuit for a solid-state image sensing device as an example, it is not limited to this.

It is apparent that the present invention is not limited to the above embodiment and it may be modified and changed without departing from the scope and spirit of the invention.

What is claimed is:

1. An output circuit comprising:
a first amplifier that is supplied with power via a first power supply line that receives an input signal; and
a second amplifier that further amplifies a signal amplified by the first amplifier and is supplied with power via a second power supply which is independent from the first power supply line.

2. The output circuit according to claim 1, further comprising:
a first source follower circuit that is inputted with a signal amplified by the second amplifier and is supplied with power via the second power supply line.

3. The output circuit according to claim 1, further comprising:
a second source follower circuit that is inputted with a signal amplified by the first amplifier and is supplied with power via the first power supply line.

4. The output circuit according to claim 1, wherein the first and the second amplifiers are inverting amplifiers.

5. The output circuit according to claim 1, wherein the output circuit amplifies and outputs a signal charge in a solid-state imaging apparatus.

6. An output circuit comprising:
a first amplifier that receives a first input signal;
a second amplifier that further amplifies a signal that is amplified by the first amplifier;
a third amplifier that receives a second input signal;
a fourth amplifier that further amplifies a signal that is amplified by the third amplifier;
a fifth amplifier that receives a third input signal; and
a sixth amplifier that further amplifies a signal that is amplified by the fifth amplifier,
wherein the first, third, and fifth amplifiers are supplied with power via a first power supply line, while the second, fourth, and sixth amplifiers are supplied with power via a second power supply line which is independent from the first power supply line.

7. The output circuit according to claim 6, further comprising:
a first source follower circuit that is inputted with a signal amplified by the second amplifier and is supplied with power via the second power supply line;
a second source follower circuit that is inputted with a signal amplified by the fourth amplifier and is supplied with power via the second power supply line; and
a third source follower circuit that is inputted with a signal amplified by the sixth amplifier and is supplied with power via the second power supply line.

8. The output circuit according to claim 6, further comprising:
a fourth source follower circuit that is inputted with a signal amplified by the first amplifier and is supplied with power via the first power supply line;
a fifth source follower circuit that is inputted with a signal amplified by the third amplifier and is supplied with power via the third power supply line; and
a sixth source follower circuit that is inputted with a signal amplified by the fifth amplifier and is supplied with power via the fifth power supply line.

9. The output circuit according to claim 6, wherein the first, second, third, fourth, fifth and sixth amplifiers are inverting amplifiers.

10. The output circuit according to claim 6, wherein
the output circuit amplifies and outputs a signal charge in a solid-state image sensing apparatus, and
the first, second, and third signals each correspond with different colors.
